(19) United States
(12) Patent Application Publication
(10) Pub. No.: US 2010/0253551 A1
(43) Pub. Date: Oct. 7, 2010

(54) KEYBOARD WITH PAINT SCHEME

(75) Inventor: HUO-LU TSAI, Ta Ya Shiang (TW)

Correspondence Address: G. LINK CO., LTD., 3550 BELL ROAD, MINOKA, IL, 60447, US

(73) Assignee: Sunrex Technology Corp., Ta Ya Shiang, (TW)

(21) Appl. No.: 12/419,752

(22) Filed: Apr. 7, 2009

(51) Int. Cl. H03M 11/00; B05D 5/00

(52) U.S. Cl. 341/22; 427/58

(57) ABSTRACT

A keyboard includes a seat; a plurality of keys positioned on the seat, the key comprising a vertically depressible bridge and a cap releasably fastened on the bridge; a plurality of primers each formed on the cap; a plurality of paint layers each coated on the primer wherein each of a predetermined number of the paint layers has a piece of a paint scheme selected from a computer; and a plurality of character layers each having a unique character set coated on the paint layer. The keyboard is aesthetic. Further, such type of keyboard featured a specially designed paint scheme on exterior is very competitive in the market.

### BACKGROUND OF THE INVENTION

1. Field of Invention

The invention relates to computer keyboards and more particularly to such a keyboard featured a paint scheme on exterior.

2. Description of Related Art

The availability of various new high-technology products (e.g., computers) is even faster as information technology and electronics make progress significantly in recent several decades. The fast development of such new products is closely tied to our daily life and work. Thus, it is impossible of doing without them.

Conventionally, the most common input device of a personal computer is keyboard. However, conventional keyboards are monotonous (e.g., having a color of gray, white or black) so far as the inventor is aware. In one point of view, it is not visually attractive. In another point of view, monotonous keyboards may not survive in this competitive market. Thus, a need for improvement exists.

### SUMMARY OF THE INVENTION

It is therefore one object of the invention to provide a keyboard featured a paint scheme on exterior so as to not only be more visually attractive but also be more competitive in the market.

In one aspect of the invention there is provided a keyboard comprising a seat; a plurality of keys positioned on the seat, the key comprising a vertically depressible bridge and a cap releasably fastened on the bridge; a plurality of primers each formed on the cap; a plurality of paint layers each coated on the primer wherein each of a predetermined number of the paint layers has a piece of a paint scheme selected from a computer; and a plurality of character layers each having a unique character set coated on the paint layer.

In another aspect of the invention there is provided a process of manufacturing a keyboard comprising the steps of positioning a plurality of keys on a seat, the key comprising a vertically depressible bridge and a cap releasably fastened on the bridge; forming a primer on each of the caps to assemble a plurality of half-finished keyboards; selecting a paint scheme from a computer; conveying the half-finished keyboards to a coating machine electrically connected to the computer wherein positions of a plurality of pieces of the paint scheme to be coated on tops of a predetermined number of the plurality of keys are determined by the computer by running a predetermined program; activating the coating machine to coat the paint scheme on the primers; and coating a transparent protective layer on the primer of each cap.

The above and other objects, features and advantages of the invention will become apparent from the following detailed description taken with the accompanying drawings.

### BRIEF DESCRIPTION OF THE DRAWINGS

FIG. 1 is a top plan view of a preferred embodiment of keyboard according to the invention;

FIG. 2 is a longitudinal sectional view of the key; and

FIG. 3 a detailed view of the area in circle A in FIG. 2.

### DETAILED DESCRIPTION OF THE INVENTION

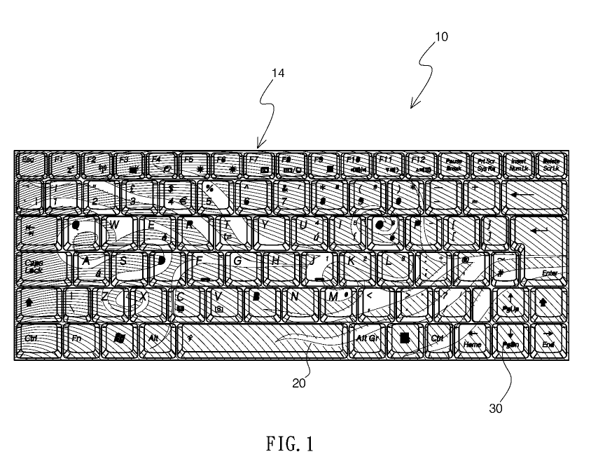

Referring to FIGS. 1 to 3, a keyboard in accordance with a preferred embodiment of the invention is generally designated by numeral 10. While the keyboard 10 is shown as a computer keyboard, the characteristics of the invention can be equally applied to other electronic products having similar input devices.

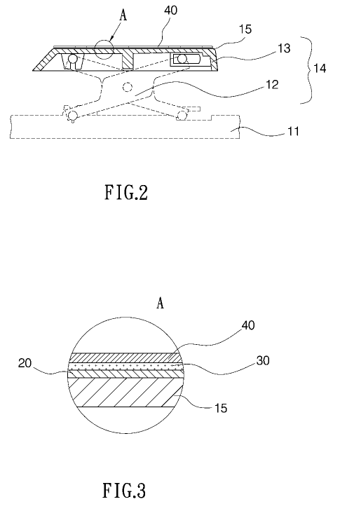

The keyboard 10 comprises a rectangular seat 11 with a plurality of keys 14 positioned thereon. The key 14 comprises a vertically depressible bridge 12 having a longitudinal section of “X” as shown in FIG. 2. The key 14 further comprises a cap 13 releasably fastened on the bridge 12. A primer 15 is formed on the substantially flat top of each of the caps 13. The keyboards 10 having the above components are half-finished products.

A desired paint scheme can be selected from a computer. Next, positions of pieces of the paint scheme to be coated on tops of some of the plurality of keys 14 are determined by the computer by running a predetermined program. Next, a plurality of paint layers 20 each is coated on one of the primers 15 using a coating machine (not shown) electrically connected to the computer in which each of some of the paint layers 20 has a piece of the paint scheme as determined by the computer.

Further, a character layer 30 having a unique character set is coated on each of the paint layers 20 using the coating machine.

Finally, a transparent protective layer 40 is coated on each character layer 30 using the coating machine. Hence, the character set and the complete paint scheme on the keys 14 can be clearly seen through the transparent protective layers 40 when the keys 14 are manufactured. Moreover, the provision of the transparent protective layers 40 can protect both the character layers 30 and the paint layers 20 therebelow.

It is envisaged by the invention that an aesthetic keyboard 10 can be manufactured by the invention. It is further contemplated by the invention that such type of keyboard featured a specially designed paint scheme on exterior of the keys 14 is very competitive in the market.

A process of manufacturing the keyboard of the invention comprises the following steps:

A plurality of keys are positioned on a seat of a keyboard in which the key comprises a vertically depressible bridge and a cap releasably fastened on the bridge.

A primer is formed on the substantially flat top of each of the caps.

The half-finished keyboards are conveyed to a coating machine.

A desired paint scheme is selected from a computer.

Positions of pieces of the paint scheme to be coated on tops of some of the plurality of keys 14 are determined by the computer by running a predetermined program.

A plurality of paint layers 20 each is coated on one of the primers 15 using a coating machine (not shown) electrically connected to the computer in which each of some of the paint layers 20 has a piece of the paint scheme as determined by the computer.

A character layer 30 having a unique character set is coated on each of the paint layers 20 using the coating machine.

A transparent protective layer 40 is coated on each character layer 30 using the coating machine so that a complete paint scheme can be formed when the keys 14 are manufactured.

While the invention herein disclosed has been described by means of specific embodiments, numerous modifications and variations could be made thereto by those skilled in the art without departing from the scope and spirit of the invention set forth in the claims.

What is claimed is:

1. A keyboard comprising:
a seat;
a plurality of keys positioned on the seat, the key comprising a vertically depressible bridge and a cap releasably fastened on the bridge;
a plurality of primers each formed on the cap;
a plurality of paint layers each coated on the primer wherein each of a predetermined number of the paint layers has a piece of a paint scheme selected from a computer; and
a plurality of character layers each having a unique character set coated on the paint layer.

2. The keyboard of claim 1, further comprising a plurality of transparent protective layers each coated on the character layer.

3. The keyboard of claim 1, wherein both the paint layers and the character layers are sequentially coated on the primers using a coating machine.

4. A process of manufacturing a keyboard comprising the steps of:
positioning a plurality of keys on a seat, the key comprising a vertically depressible bridge and a cap releasably fastened on the bridge;
forming a primer on each of the caps to assemble a plurality of half-finished keyboards;
selecting a paint scheme from a computer;
conveying the half-finished keyboards to a coating machine electrically connected to the computer wherein positions of a plurality of pieces of the paint scheme to be coated on tops of a predetermined number of the plurality of keys are determined by the computer by running a predetermined program;
activating the coating machine to coat the paint scheme on the primers; and
coating a transparent protective layer on the primer of each cap.

5. The process of claim 4, wherein each of the plurality of pieces of the paint scheme comprises a paint layer and a character layer coated thereon.
